(19) United States
(12) Patent Application Publication
(10) Pub. No.: US 2025/0098425 A1
(43) Pub. Date: Mar. 20, 2025

(54) DISPLAY SUBSTRATE AND DISPLAY DEVICE

(71) Applicants: HEFEI BOE JOINT TECHNOLOGY CO., LTD., Hefei (CN); BOE TECHNOLOGY GROUP CO., LTD., Beijing (CN)

(72) Inventors: Rui PENG, Beijing (CN); Minghung HSU, Beijing (CN); Yue HU, Beijing (CN)

(21) Appl. No.: 18/555,039

(22) PCT Filed: Jan. 18, 2023
(86) PCT No.: PCT/CN2023/072971

§ 371 Date: Oct. 12, 2023

(51) Int. Cl. H10K 59/122; H10K 59/80

(52) U.S. Cl. CPC H10K 59/122; H10K 59/879

(57) ABSTRACT

A display substrate and a display device are disclosed. The display substrate includes a pixel defining layer, the pixel defining layer includes a pixel defining structure and a plurality of grooves, the plurality of grooves are arranged along a first direction, the groove extends along a second direction, and the second direction intersects with the first direction; the pixel defining structure includes a plurality of first defining portions in the groove and arranged along the second direction, and the first defining portion extends along the first direction; and two adjacent first defining portions in a same groove are configured to define a sub-pixel group, and the sub-pixel group includes a plurality of sub-pixels.

### TECHNICAL FIELD

Embodiments of the present disclosure relate to a display substrate and a display device.

### BACKGROUND

With the rapid development of science and technology, display media has become an important part of people's lives. An organic light emitting-diode (OLED) display medium has excellent color and image quality due to its self-luminescence.

### SUMMARY

The embodiments of the present disclosure provide a display substrate and a display device to enhance brightness uniformity.

In an aspect, the embodiment of the present disclosure provides a display substrate, comprising a pixel defining layer, wherein the pixel defining layer comprises a pixel defining structure and a plurality of grooves, the plurality of grooves are arranged along a first direction, the groove extends along a second direction, and the second direction intersects with the first direction; the pixel defining structure comprises a plurality of first defining portions in the groove and arranged along the second direction, and the first defining portion extends along the first direction; and two adjacent first defining portions in a same groove are configured to define a sub-pixel group, and the sub-pixel group comprises a plurality of sub-pixels.

For example, a short edge of the sub-pixel corresponds to a long edge of the sub-pixel group.

For example, the plurality of sub-pixels are arranged sequentially along an extension direction of a long edge of the sub-pixel group.

For example, an extension direction of a long edge of the sub-pixel is identical to an extension direction of a short edge of the sub-pixel group, and an extension direction of a short edge of the sub-pixel is identical to an extension direction of a long edge of the sub-pixel group.

For example, the pixel defining structure further comprises a second defining portion between two adjacent first defining portions, the second defining portion extends along the first direction, and the second defining portion is configured to separate two adjacent sub-pixels in a same sub-pixel group.

For example, a plurality of second defining portions are provided, and the plurality of second defining portions are arranged along the second direction.

For example, the display substrate further comprises a base substrate, wherein the pixel defining layer is on the base substrate, and a dimension of the first defining portion in a direction perpendicular to the base substrate is greater than or equal to a dimension of the second defining portion in the direction perpendicular to the base substrate.

For example, the pixel defining structure further comprises a plurality of main defining portions, the groove is between two adjacent main defining portions of the plurality of main defining portions, and a dimension of the main defining portion in a direction perpendicular to the base substrate is greater than a dimension of the first defining portion in the direction perpendicular to the base substrate.

For example, a dimension of the first defining portion along the second direction is greater than or equal to a dimension of the second defining portion along the second direction.

For example, the display substrate further comprises a lens layer, wherein the lens layer comprises a plurality of lens units, an extension direction of the lens unit is identical to an extension direction of a long edge of the sub-pixel, and the lens unit covers at least one sub-pixel.

For example, the pixel defining layer comprises a plurality of openings penetrating through the pixel defining structure; the opening is configured to define a light-emitting region of a sub-pixel, and the sub-pixel group comprises more than one opening.

For example, the extension direction of the groove is identical to the extension direction of the short edge of the sub-pixel.

For example, a cross-sectional shape of the lens unit comprises a column, a triangle, or a semicircle.

For example, different sub-pixel groups correspond to different structures of lens units.

For example, an orthographic projection of the lens unit on a base substrate overlaps with an orthographic projection of the first defining portion on the base substrate.

For example, each of the sub-pixels comprised in the sub-pixel group is driven by an independent pixel circuit.

In another aspect, the embodiment of the present disclosure provides a display substrate, comprising a pixel defining layer, wherein: the pixel defining layer comprises a pixel defining structure and a plurality of openings penetrating through the pixel defining structure; the pixel defining structure comprises a plurality of main defining portions, the plurality of main defining portions are arranged along a first direction, the main defining portion extends along a second direction, and the second direction intersects with the first direction; the pixel defining structure further comprises a plurality of first defining portions between two adjacent main defining portions and arranged along the second direction, and the first defining portion extends along the first direction; the pixel defining structure further comprises a second defining portion between two adjacent first defining portions, the second defining portion extends along the first direction; and two adjacent main defining portions and two adjacent first defining portions between the two adjacent main defining portions are configured to define a sub-pixel group, and the sub-pixel group comprises a plurality of sub-pixels.

In the display substrate provided by the embodiment of the present disclosure, a short edge of the sub-pixel corresponds to a long edge of the sub-pixel group

In the display substrate provided by the embodiment of the present disclosure, the plurality of sub-pixels are arranged sequentially along an extension direction of a long edge of the sub-pixel group.

In the display substrate provided by the embodiment of the present disclosure, an extension direction of a long edge of the sub-pixel is identical to an extension direction of a short edge of the sub-pixel group, and an extension direction of a short edge of the sub-pixel is identical to an extension direction of a long edge of the sub-pixel group.

In the display substrate provided by the embodiment of the present disclosure, the display substrate further comprises a base substrate, wherein the pixel defining layer is on the base substrate, and a dimension of the first defining portion in a direction perpendicular to the base substrate is greater than or equal to a dimension of the second defining portion in the direction perpendicular to the base substrate.

In the display substrate provided by the embodiment of the present disclosure, a dimension of the main defining portion in a direction perpendicular to the base substrate is greater than a dimension of the first defining portion in the direction perpendicular to the base substrate.

In the display substrate provided by the embodiment of the present disclosure, a dimension of the first defining portion along the second direction is greater than a dimension of the second defining portion along the second direction.

In the display substrate provided by the embodiment of the present disclosure, the display substrate further comprises a light-emitting element, wherein the light-emitting element comprises a first electrode, a second electrode, and a light-emitting functional layer between the first electrode and the second electrode, and the opening is configured to expose a portion of the first electrode.

In the display substrate provided by the embodiment of the present disclosure, an extension direction of the main defining portion is identical to an extension direction of a short edge of the sub-pixel.

In the display substrate provided by the embodiment of the present disclosure, a cross-sectional shape of the lens unit comprises a column, a triangle, or a semicircle.

In the display substrate provided by the embodiment of the present disclosure, different sub-pixel groups correspond to different structures of lens units.

In the display substrate provided by the embodiment of the present disclosure, an orthographic projection of the lens unit on a base substrate overlaps with an orthographic projection of the first defining portion on the base substrate.

In the display substrate provided by the embodiment of the present disclosure, each of the sub-pixels comprised in the sub-pixel group is driven by an independent pixel circuit.

In yet another aspect, the embodiment of the present disclosure further provides a display device which comprises any of the afore-mentioned display substrate.

### BRIEF DESCRIPTION OF DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic diagram of a display substrate;

FIG. 2 is a schematic diagram of a display substrate provided by an embodiment of the present disclosure;

FIG. 3 is a cross-sectional view of FIG. 2 along a line A1-A2;

FIG. 4 is a cross-sectional view of FIG. 2 along a line A3-A4;

FIG. 5 is a cross-sectional view of FIG. 2 along a line A5-A6;

FIG. 6 is a schematic diagram of a display substrate provided by an embodiment of the present disclosure;

FIG. 7 is a cross-sectional view of a display substrate provided by an embodiment of the present disclosure;

FIG. 8 is a cross-sectional view of another display substrate provided by an embodiment of the present disclosure;

FIG. 9 is a cross-sectional view of another display substrate provided by an embodiment of the present disclosure;

FIG. 10 is a cross-sectional view of another display substrate provided by an embodiment of the present disclosure;

FIG. 11 is a schematic diagram of a display substrate provided by an embodiment of the present disclosure;

FIG. 12 is a schematic diagram of another display substrate provided by an embodiment of the present disclosure;

FIG. 13 is a schematic diagram of a display substrate provided by an embodiment of the present disclosure;

FIG. 14 is a cross-sectional view of FIG. 13 along a line B1-B2;

FIG. 15 is a cross-sectional view of FIG. 13 along a line B3-B4;

FIG. 16 is a schematic diagram of a film thickness uniformity of a long edge of a sub-pixel of the display substrate illustrated in FIG. 1;

FIG. 17 is a schematic diagram of a film thickness uniformity of a short edge of a sub-pixel of the display substrate illustrated in FIG. 1;

FIG. 18 is a schematic diagram of a film thickness uniformity of a long edge of a sub-pixel of the display substrate illustrated in FIG. 2; and

FIG. 19 is a schematic diagram of a film thickness uniformity of a short edge of a sub-pixel of the display substrate illustrated in FIG. 2.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

Inkjet printing, as a process method for preparing organic light-emitting diodes (OLEDs) in solution type, suffers from poor uniformity of the film thickness on the short edge due to the climbing, pinning, and “coffee-ring” effects of the solution-based inks, resulting in poor brightness uniformity.

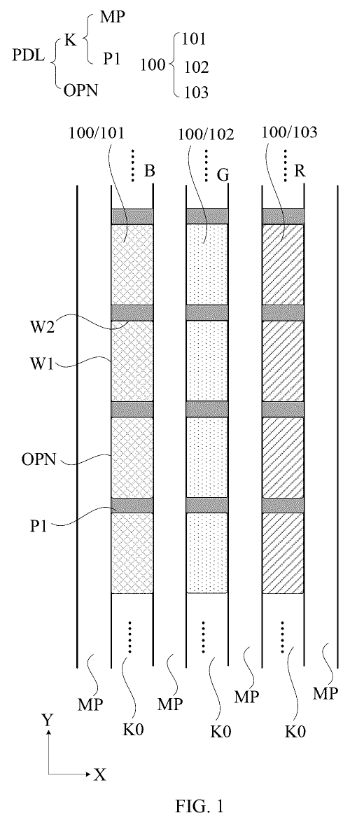

FIG. 1 is a schematic diagram of a display substrate. As illustrated in FIG. 1, the display substrate includes a pixel defining layer PDL. As illustrated in FIG. 1, the pixel defining layer PDL includes a pixel defining structure K and a plurality of openings OPN, the pixel defining structure K includes a main defining portion MP, a plurality of the main defining portions MP are arranged along a first direction X, and the main defining portion MP extends along a second direction Y; a groove KO is provided between two adjacent main defining portions MP, a plurality of grooves KO are arranged along the first direction X, the groove KO extends along the second direction Y, and the second direction Y intersects with the first direction X. The pixel defining structure K further includes a plurality of defining portions P1 in the groove KO and arranged along the second direction Y, and the defining portion P1 extends along the first direction X. As illustrated in FIG. 1, the region between two adjacent defining portions P1 in the same groove KO is the opening OPN. As illustrated in FIG. 1, the opening OPN corresponds to one sub-pixel 100. FIG. 1 illustrates a sub-pixel 101, a sub-pixel 102, and a sub-pixel 103. When a light-emitting functional layer of a light-emitting element is manufactured by the inkjet printing process, the inks in the same groove KO have the same color. The sub-pixels 100 in the same groove KO emit light of the same color. FIG. 1 takes the case where the sub-pixel 101 is a blue sub-pixel, the sub-pixel 102 is a green sub-pixel, and the sub-pixel 103 is a red sub-pixel as an example for illustration.

FIG. 1 illustrates four main defining portions MP sequentially arranged along the first direction X. FIG. 1 illustrates three grooves KO. During the inkjet printing process, the same groove KO is used to accommodate the same type of ink. The sub-pixels 100 in the same groove KO emit light of the same color. FIG. 1 illustrates four defining portions P1 in the same groove KO, the four defining portions P1 are spaced apart from each other and arranged sequentially along the second direction Y. It can be contemplated that the total number of the main defining portions MP and the total number of the defining portions P1 in the display substrate may be determined according to needs.

As illustrated in FIG. 1, the sub-pixel 100 is provided with a long edge W1 and a short edge W2. The length of the long edge W1 is greater than the length of the short edge W2. Due to the climbing, pinning, and “coffee ring” effects of the solution-based inks, a film thickness uniformity at the short edge is poor, which in turn leads to the problem of poor brightness uniformity.

In order to solve the problem of poor brightness uniformity caused by poor uniformity of film thickness at the short edge, the embodiments of the present disclosure provide a display substrate.

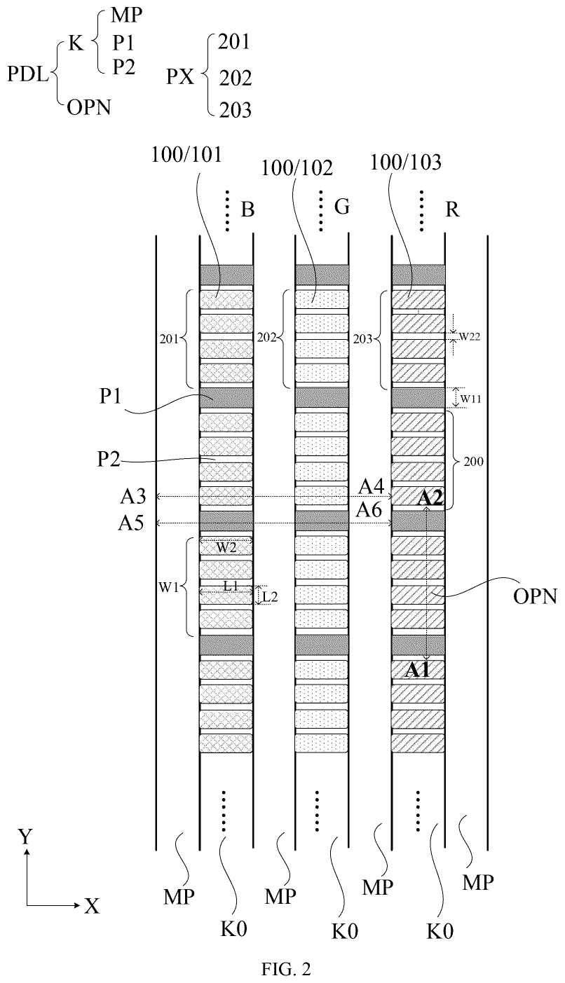

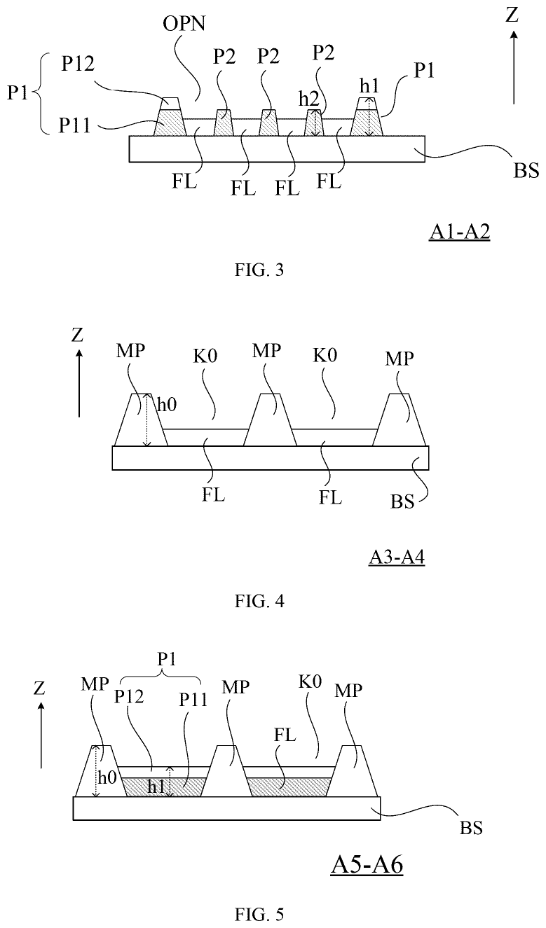

FIG. 2 is a schematic diagram of a display substrate provided by an embodiment of the present disclosure. FIG. 3 is a cross-sectional view of FIG. 2 along a line A1-A2. FIG. 4 is a cross-sectional view of FIG. 2 along a line A3-A4. FIG. 5 is a cross-sectional view of FIG. 2 along a line A5-A6.

As illustrated in FIG. 2 to FIG. 5, the display substrate includes a pixel defining layer PDL, the pixel defining layer PDL includes a pixel defining structure K, the pixel defining structure K includes a plurality of grooves KO, the plurality of grooves KO are arranged along the first direction X, the groove KO extends along the second direction Y, and the second direction Y intersects with the first direction X; the pixel defining structure K further includes a plurality of first defining portions P1 in the groove KO and arranged along the second direction Y, and the first defining portion P1 extends along the first direction X; and two adjacent first defining portions P1 in the same groove KO are configured to define a sub-pixel group 200, and the sub-pixel group 200 includes a plurality of sub-pixels 100.

In the display substrate provided by the embodiments of the present disclosure, one sub-pixel group 200 is provided between two adjacent first defining portions P1, and the sub-pixel group 200 includes a plurality of sub-pixels 100, which can alleviate the problem of poor brightness uniformity caused by poor uniformity of the film thickness at the short edge of the sub-pixel, as compared to the case in which the sub-pixel group 200 includes one sub-pixel 100. The film thickness uniformity of the display substrate provided by the embodiments of the present disclosure is optimized, and the display substrate has better brightness uniformity.

The above-mentioned embodiment is described based on a perspective that two adjacent first defining portions P1 in the same groove KO are configured to define a sub-pixel group 200. It can be contemplated that, the embodiment may be described in other ways, for example, the following description is based on a perspective that two adjacent main defining portions MP and two adjacent first defining portions P1 between the two adjacent main defining portions MP are configured to define a sub-pixel group.

As illustrated in FIG. 2, the display substrate provided by an embodiment of the present disclosure includes a pixel defining layer PDL, and the pixel defining layer PDL includes a pixel defining structure K and a plurality of openings OPN penetrating through the pixel defining structure K; the pixel defining structure K includes a plurality of main defining portions MP, the plurality of main defining portions MP are arranged along the first direction X, the main defining portion MP extends along the second direction Y, and the second direction Y intersects with the first direction X; the pixel defining structure K further includes a plurality of first defining portions P1 between two adjacent main defining portions MP and arranged along the second direction Y, and the first defining portion P1 extends along the first direction X; the pixel defining structure K further includes a second defining portion P2 between two adjacent first defining portions P1, and the second defining portion P2 extends along the first direction X; and two adjacent main defining portions MP and two adjacent first defining portions P1 between the two adjacent main defining portions MP are configured to define a sub-pixel group 200, and the sub-pixel group 200 includes a plurality of sub-pixels 100.

In the display substrate provided by the embodiments of the present disclosure, two adjacent main defining portions MP and two adjacent first defining portions P1 between the two adjacent main defining portions MP are configured to define a sub-pixel group 200, and the sub-pixel group 200 includes a plurality of sub-pixels 100, which can alleviate the problem of poor brightness uniformity caused by poor uniformity of the film thickness at the short edge of the sub-pixel, as compared to the case in which the sub-pixel group 200 includes one sub-pixel 100. The film thickness uniformity of the display substrate provided by the embodiments of the present disclosure is optimized, and the display substrate has better brightness uniformity.

In the display substrate provided by the embodiments of the present disclosure, the sub-pixel group 200 includes a plurality of sub-pixels 100, which is beneficial to increase the total number of pixels per inch (PPI).

In some embodiments, as illustrated in FIG. 2, a groove KO is provided between two adjacent main defining portions MP, a plurality of grooves KO are arranged along the first direction X, and the groove KO extends along the second direction Y.

As illustrated in FIG. 2, the sub-pixel group 200 has a long edge W1 and a short edge W2, and the length of the long edge W1 is greater than the length of the short edge W2.

As illustrated in FIG. 2, the sub-pixel 100 has a long edge L1 and a short edge L2, and the length of the long edge L1 is greater than the length of the short edge L2.

For example, as illustrated in FIG. 2, the short edge L2 of the sub-pixel 100 corresponds to the long edge W1 of the sub-pixel group 200. As illustrated in FIG. 2, the sub-pixel 100 extends along the extension direction of the short edge W2 of the sub-pixel group 200, and a plurality of sub-pixels 100 are arranged along the extension direction of the long edge W1 of the sub-pixel group 200.

In some embodiments, as illustrated in FIG. 2, the plurality of sub-pixels 100 are sequentially arranged along the extension direction of the long edge of the sub-pixel group 200.

In some embodiments, as illustrated in FIG. 2, the extension direction of the long edge of the sub-pixel 100 is identical to the extension direction of the short edge of the sub-pixel group 200, and the extension direction of the short edge of the sub-pixel 100 is identical to the extension direction of the long edge of the sub-pixel group 200.

FIG. 2 takes the case where the sub-pixel group 200 includes four sub-pixels 100 as an example for illustration. For example, the sub-pixel group 200 includes 4 to 15 sub-pixels 100. For another example, in order to better improve brightness uniformity, the sub-pixel group 200 includes 8 to 15 sub-pixels 100. It can be contemplated that the embodiments of the present disclosure do not limit the total number of sub-pixels 100 included in the sub-pixel group 200.

In the embodiments of the present disclosure, the sub-pixel 100 is the smallest light-emitting unit, and the sub-pixel 100 can be independently controlled. For example, respective sub-pixels 100 are driven by different pixel circuits.

For example, as illustrated in FIG. 2 and FIG. 3, due to the electrical conductivity of the ink, in order to avoid the electricity leakage of the sub-pixel 100 and facilitate the independent control of the sub-pixel 100, the display substrate further includes a second defining portion P2 provided between two adjacent first defining portions P1. As illustrated in FIG. 2, the second defining portion P2 extends along the first direction X.

For example, as illustrated in FIG. 2 and FIG. 3, a plurality of second defining portions P2 are provided. As illustrated in FIG. 2, the plurality of second defining portions P2 are arranged along the second direction Y. FIG. 2 and FIG. 3 illustrate three second defining portions P2 arranged sequentially at intervals between two adjacent first defining portions P1. The second defining portion P2 is configured to separate two adjacent sub-pixels 100 in the same sub-pixel group 200.

FIG. 2 illustrates four main defining portions MP sequentially arranged along the first direction X. FIG. 2 illustrates three grooves KO. During the inkjet printing process, the same groove KO is used to accommodate the same type of ink. The sub-pixels 100 in the same groove KO emit light of the same color. FIG. 2 illustrates four first defining portions P1 in the same groove KO and the four first defining portions P1 are spaced apart and arranged sequentially along the second direction Y. FIG. 2 further illustrates three second defining portions P2 between two adjacent first defining portions P1. Certainly, the total number of the main defining portions MP, the total number of the first defining portions P1, and the total number of the second defining portions P2 in the display substrate may be determined according to needs.

For example, as illustrated in FIG. 3 to FIG. 5, the display substrate further includes a base substrate BS, and the pixel defining layer PDL on the base substrate BS. As illustrated in FIG. 3, the dimension h1 of the first defining portion P1 in a direction perpendicular to the base substrate BS is greater than the dimension h2 of the second defining portion P2 in the direction perpendicular to the base substrate BS.

As illustrated in FIG. 3 and FIG. 5, the first defining portion P1 includes a first defining sub-layer P11 and a second defining sub-layer P12, and the first defining sub-layer P11 is closer to the base substrate BS than the second defining sublayer P12. For example, the first defining sub-layer P11 is made of hydrophilic material, and the second defining sub-layer P12 is made of hydrophobic material, but not limited thereto. It can be contemplated that the first defining portion P1 may also adopt a single-layer structure, or include more than two defining sub-layers.

For example, as illustrated in FIG. 2, FIG. 4 and FIG. 5, the pixel defining structure K further includes a plurality of main defining portions MP. As illustrated in FIG. 2, a groove KO is between two adjacent main defining portions MP. As illustrated in FIG. 5, the dimension h0 of the main defining portion MP in the direction perpendicular to the base substrate BS is greater than the dimension h1 of the first defining portion P1 in the direction perpendicular to the base substrate BS. FIG. 5 takes the case where the first defining portion P1 includes the first defining sub-layer P11 and the second defining sub-layer P12, and the main defining portion MP and the first defining portion P1 are fabricated respectively as an example. In other embodiments, the main defining portion MP and one of the first defining sub-layer P11 and the second defining sub-layer P12 may be formed of the same film layer by using the same patterning process.

As illustrated in FIG. 4 and FIG. 5, the dimension h0 of the main defining portion MP in the direction perpendicular to the base substrate BS is equal to the dimension of the groove KO in the direction perpendicular to the base substrate BS. Thus, the dimension of the groove KO in the direction perpendicular to the base substrate BS is greater than the dimension h1 of the first defining portion P1 in the direction perpendicular to the base substrate BS, and the dimension h1 of the first defining portion P1 in the direction perpendicular to the base substrate BS is greater than the dimension h2 of the second defining portion P2 in the direction perpendicular to the base substrate BS.

For example, as illustrated in FIG. 2, the pixel defining layer PDL further includes a plurality of openings OPN penetrating through the pixel defining structure K, the opening OPN is configured to define the light-emitting region of one sub-pixel 100, and the sub-pixel group 200 includes more than one opening OPN. FIG. 2 and FIG. 3 takes the case where the sub-pixel group 200 includes four openings OPN as an example for illustration. It can be contemplated that the total number of the openings OPN included in the sub-pixel group 200 may be determined according to needs.

For example, as illustrated in FIG. 2, the dimension W11 of the first defining portion P1 along the second direction Y is greater than the dimension W22 of the second defining portion P2 along the second direction Y.

As illustrated in FIG. 2, the pixel PX includes a plurality of sub-pixel groups 200, and FIG. 2 takes the case where the pixel PX includes three sub-pixel groups 200 as an example for illustration. FIG. 2 illustrates a sub-pixel group 201, a sub-pixel group 202, and a sub-pixel group 203. As illustrated in FIG. 2, in a plurality of sub-pixel groups 200 included in the pixel PX, the plurality of sub-pixel groups 200 are configured to emit light of different colors, and the plurality of sub-pixels 100 in the same sub-pixel group 200 are configured to emit light of the same color. FIG. 2 takes the case where the sub-pixel 101 is a blue sub-pixel, the sub-pixel 102 is a green sub-pixel, and the sub-pixel 103 is a red sub-pixel as an example or illustration. Therefore, the sub-pixels 101 in the sub-pixel group 201 are blue sub-pixels, the sub-pixels 102 in the sub-pixel group 202 are green sub-pixels, and the sub-pixels 103 in the sub-pixel group 203 are red sub-pixels. The light-emitting colors of the sub-pixels are not limited to the above-mentioned description, and may be determined according to needs.

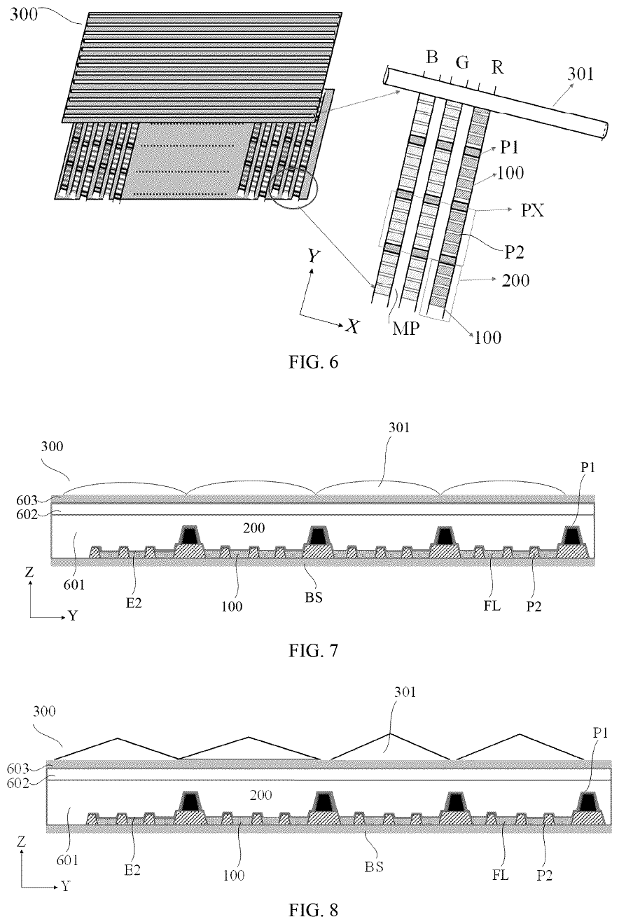

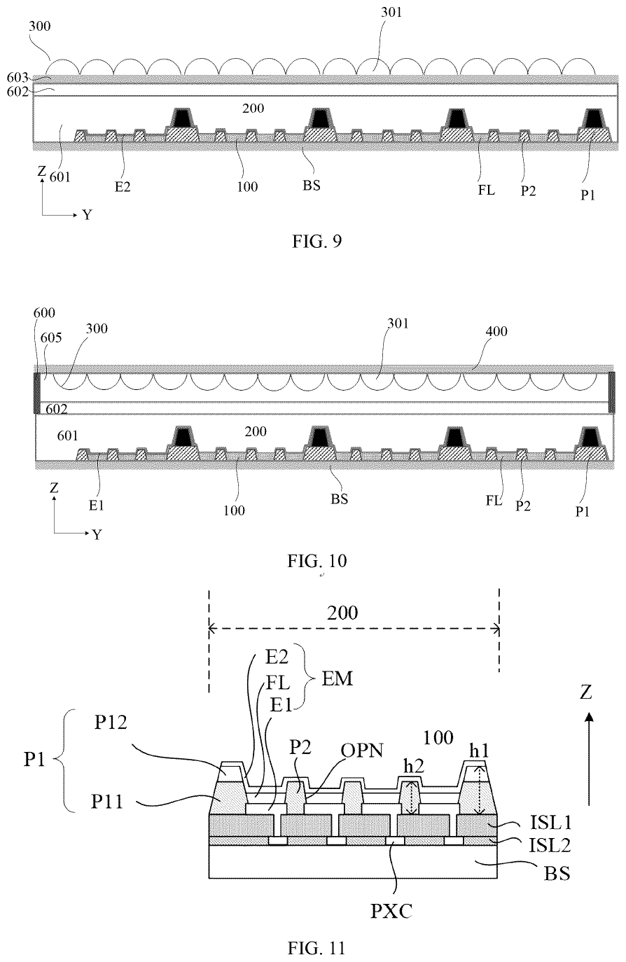

FIG. 6 is a schematic diagram of a display substrate provided by an embodiment of the present disclosure. FIG. 7 is a cross-sectional view of a display substrate provided by an embodiment of the present disclosure. FIG. 8 is a cross-sectional view of another display substrate provided by an embodiment of the present disclosure. FIG. 9 is a cross-sectional view of another display substrate provided by an embodiment of the present disclosure. FIG. 10 is a cross-sectional view of another display substrate provided by an embodiment of the present disclosure.

For example, as illustrated in FIG. 6 to FIG. 8, the display substrate further includes a lens layer 300, and the lens layer 300 includes a plurality of lens units 301, exemplarily, the extension direction of the lens unit 301 is identical to the extension direction of the long edge L1 of the sub-pixel 100. The display substrate is provided with the lens layer 300 for 3D display. The extension direction of the lens unit 301 is identical to the extension direction of the long edge L1 of the sub-pixel 100, which is beneficial to realize a 3D display effect with high PPI. For clarity of illustration, only one lens unit 301 is illustrated on the right side of FIG. 6.

For example, as illustrated in FIG. 6, one lens unit 301 covers a plurality of sub-pixels 100 of different colors.

FIG. 6 takes the case where the first direction X is a row direction and the second direction Y is a column direction as an example for illustration. The same column of sub-pixels are sub-pixels of the same color.

For example, the lens units 301 on the pixels PX of different rows may be set differently. For example, different sub-pixel groups 200 correspond to different structures of lens units 301. For example, different lens units 301 may be set differently. For example, the lens units 301 may have different dimensions, such as different widths. For example, the lens units 301 may have different heights. For example, at different positions, the lens units 301 may have different arrangement densities or different compactness. For example, the structural difference of the lens units 301 includes at least one selected from the group consisting of the above-mentioned difference in dimension, difference in height, difference in arrangement density, and difference in compactness.

For example, the lens layer 300 is a transparent lens layer.

For example, as illustrated in FIG. 6, the extension direction of a long edge of the lens unit 301 is identical to the extension direction of the long edge of the sub-pixel 100.

For example, as illustrated in FIG. 7 to FIG. 10, the lens unit 301 covers at least one sub-pixel 100.

As illustrated in FIG. 7 and FIG. 8, the lens unit 301 covers one sub-pixel group 200. That is, the lens unit 301 covers a plurality of sub-pixels 100 in one sub-pixel group 200.

As illustrated in FIG. 9 and FIG. 10, the lens unit 301 covers one sub-pixel 100.

As illustrated in FIG. 3 to FIG. 5 and FIG. 7 to FIG. 10, the display substrate includes a light-emitting functional layer FL. The light-emitting functional layer FL includes a plurality of film layers, for example, a light-emitting layer (light-emitting material layer), and the light-emitting functional layer may further include at least one of a hole injection layer, a hole transport layer, an electron transport layer, and an electron injection layer. The organic light-emitting functional layer may be selected according to needs. At least one film layer in the light-emitting functional layer may be manufactured by the inkjet printing process.

As illustrated in FIG. 7, the cross section of the lens unit 301 is in a shape of a column.

As illustrated in FIG. 8, the cross section of the lens unit 301 is in a shape of a triangle.

As illustrated in FIG. 9 and FIG. 10, the cross section of the lens unit 301 is in a shape of a semicircle.

As illustrated in FIG. 10, the lens layer 300 is between the base substrate BS and the base substrate 400.

For example, the protrusion direction of the lens unit 301 may be away from the base substrate BS, or toward the base substrate BS. FIG. 7 to FIG. 9 take the case where the protrusion direction of the lens unit 301 is away from the base substrate BS as an example for illustration. FIG. 10 take the case where the protrusion direction of the lens unit 301 is toward the base substrate BS as an example for illustration. No matter whether the protrusion direction of the lens unit 301 is away from the substrate or toward the substrate, the lens unit 301 can play the role of 3D display.

In the case where the protrusion direction of the lens unit 301 is away from the base substrate BS, the light extraction efficiency is effectively improved, while the pixel crosstalk problem is reduced or eliminated, the product performance is improved, and the product competitiveness is enhanced. In the case where the protrusion direction of the lens unit 301 is away from the base substrate BS, the lens unit 301 can play a role in preventing moiré pattern, i.e., play a role in atomization.

In the case where the protrusion direction of the lens unit 301 is toward the base substrate BS, the lens layer 300 may be formed on the other base substrate (for example, the base substrate 400), and then the two base substrates are bonded together. That is, in this case, the lens layer 300 and the light-emitting element EM may be provided on different base substrates, so that the lens layer 300 is easier to manufacture and the production efficiency is improved.

As illustrated in FIG. 6 to FIG. 10, the lens layer 300 is provided above the sub-pixel 100. The lens layer 300 is provided above the light-emitting element EM.

As illustrated in FIG. 6 to FIG. 10, the orthographic projection of the lens layer 300 or the lens unit 301 on the base substrate BS overlaps with the orthographic projection of the second defining portion P2 on the base substrate BS.

As illustrated in FIG. 6 to FIG. 10, the orthographic projection of the lens layer 300 or the lens unit 301 on the base substrate BS overlaps with the orthographic projection of the first defining portion P1 on the base substrate BS.

As illustrated in FIG. 6 to FIG. 10, the orthographic projection of the lens layer 300 or the lens unit 301 on the base substrate BS overlaps with the orthographic projection of the main defining portion MP on the base substrate BS.

As illustrated in FIG. 7 to FIG. 10, the display substrate further includes a second electrode E2, and the second electrode E2 is on the light-emitting functional layer FL.

As illustrated in FIG. 7 to FIG. 10, the display substrate further includes an encapsulation structure layer 601. For example, the material of the encapsulation structure layer 601 includes an inorganic material, such as silicon nitride or silicon oxynitride.

As illustrated in FIG. 7 to FIG. 10, the display substrate further includes an organic encapsulation filling layer 602. For example, the material of the organic encapsulation filling layer 602 includes an organic material, such as polyimide, but not limited thereto, and may be determined according to needs.

As illustrated in FIG. 7 to FIG. 10, the display substrate further includes a cover plate 603. For example, the cover plate 603 is made of glass, but not limited thereto.

As illustrated in FIG. 10, the display substrate further includes a gap layer 605. For example, the gap layer 605 may be filled with nitrogen. FIG. 10 further illustrates a barrier dam 600.

For the sake of clarity, FIG. 7 to FIG. 10 omit the structures between the base substrate BS and the pixel defining layer PDL.

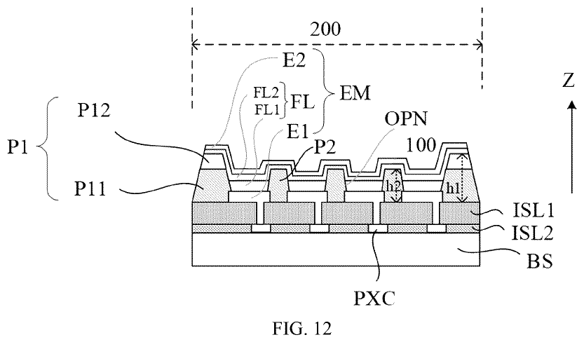

FIG. 11 is a schematic diagram of a display substrate provided by an embodiment of the present disclosure. FIG. 12 is a schematic diagram of another display substrate provided by an embodiment of the present disclosure.

As illustrated in FIG. 11 and FIG. 12, the display substrate further includes a light-emitting element EM, the light-emitting element EM includes a first electrode E1, a second electrode E2, and a light-emitting functional layer FL between the first electrode E1 and the second electrode E2, and the opening OPN is configured to expose a portion of the first electrode E1. One sub-pixel 100 includes one first electrode E1.

As illustrated in FIG. 11 and FIG. 12, a plurality of first electrodes E1 are separated from each other, so as to be configured to respectively input signals.

As illustrated in FIG. 11 and FIG. 12, the first electrode E1 is connected to a pixel circuit PXC. The pixel circuit PXC may include a transistor (T) and a storage capacitor (C), but is not limited thereto. For example, the pixel circuit PXC includes a pixel circuit such as 3T1C, 5T1C, and 5T2C, but is not limited thereto. The total number of transistors and the total number of storage capacitors included in the pixel circuit PXC may be determined according to needs.

FIG. 11 and FIG. 12 further illustrate an insulation layer ISL1 and an insulation layer ISL2. The first electrode E1 is on the insulation layer ISL1, and is connected to the pixel circuit PXC through a via hole penetrating through the insulation layer ISL1.

As illustrated in FIG. 11 and FIG. 12, the pixel circuit PXC is schematically illustrated in the figures, and the specific structure of the pixel circuit PXC may be determined according to needs.

As illustrated in FIG. 12, the light-emitting functional layer FL includes a first-type light-emitting functional layer FL1 and a second-type light-emitting functional layer FL2. The first-type light-emitting functional layer FL1 can be manufactured by inkjet printing process. The second-type light-emitting functional layer FL2 is a sharing layer and can be manufactured by evaporation. For example, the first-type light-emitting functional layer FL1 includes at least one of a hole injection layer, a hole transport layer, and a light-emitting layer, but is not limited thereto. For example, the second-type light-emitting functional layer FL2 includes an electron injection layer, but is not limited thereto. It can be contemplated that the structure of the light-emitting functional layer FL is not limited to what is illustrated in the figure, and may be determined according to needs.

For example, one of the first electrode E1 and the second electrode E2 is an anode, and the other of the first electrode E1 and the second electrode E2 is a cathode.

For example, the material of the first electrode E1 of the light-emitting element includes an electrically conductive material, for example, includes at least one of silver (Ag) or indium tin oxide (ITO), but is not limited thereto. For example, the first electrode E1 of the light-emitting element is a three-layer stacked structure of ITO/Ag/ITO, but is not limited thereto. In other embodiments, the material of the first electrode E1 of the light-emitting element includes aluminum (Al) and tungsten oxide (WOx), for example, the first electrode E1 includes a stack of an aluminum layer and a tungsten oxide layer, and the aluminum layer is closer to the base substrate than the tungsten oxide layer.

For example, the material of the second electrode E2 of the light-emitting element includes an electrically conductive material, for example, includes silver (Ag), but is not limited thereto.

For the sake of clarity, some drawings provided in the embodiments of the present disclosure do not illustrate structures such as the first electrode E1 or the pixel circuit PXC.

In the embodiments of the present disclosure, as illustrated in FIG. 11 and FIG. 12, the sub-pixels 100 can be independently controlled to display images with different gray scales, and achieve high PPI display.

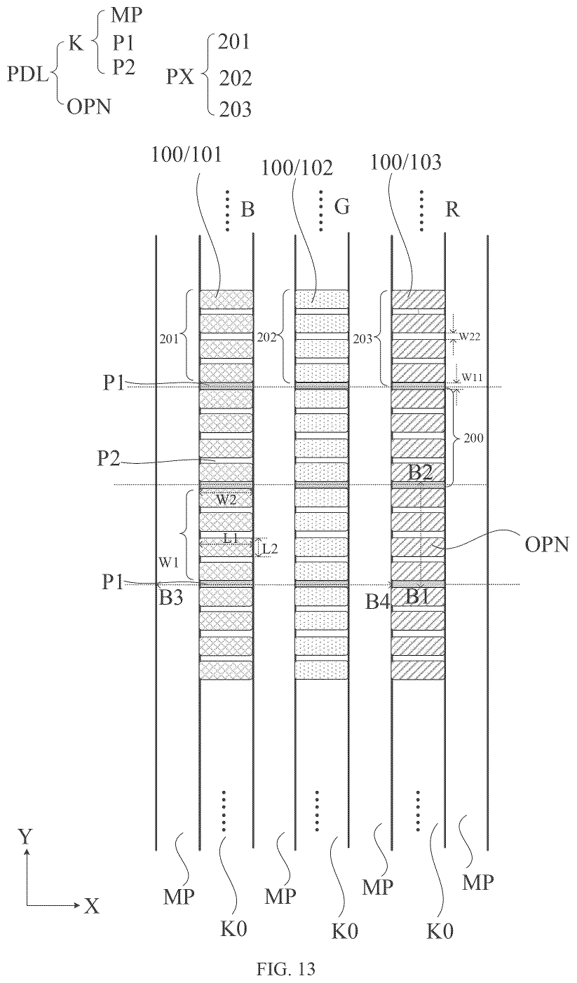

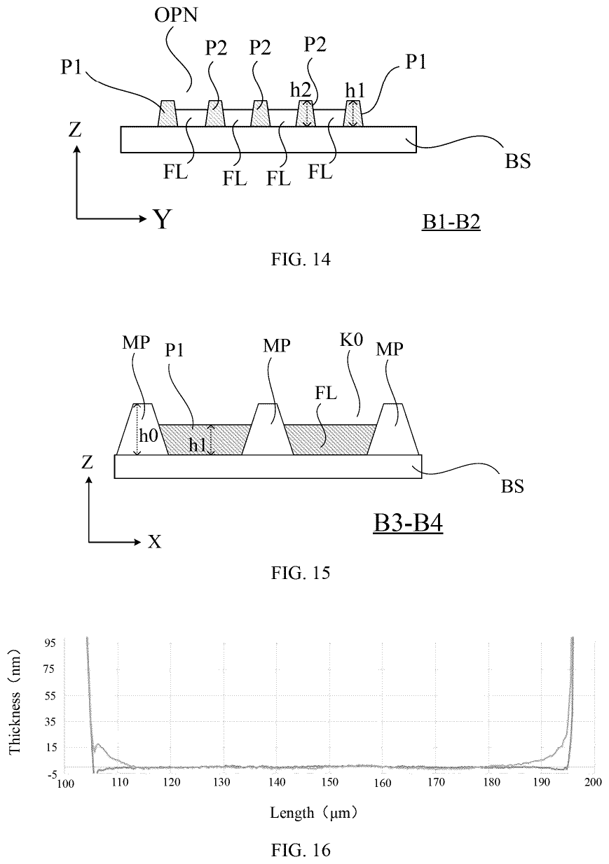

FIG. 13 is a schematic diagram of a display substrate provided by an embodiment of the present disclosure. FIG. 14 is a cross-sectional view of FIG. 13 along a line B1-B2. FIG. 15 is a cross-sectional view of FIG. 13 along a line B3-B4.

As illustrated in FIG. 13, the dimension W11 of the first defining portion P1 along the second direction Y is equal to the dimension W22 of the second defining portion P2 along the second direction Y. For example, in the embodiments of the present disclosure, “equal to” may have a margin of error within 5%. For example, the ratio of the absolute value of the difference between the dimension W11 of the first defining portion P1 along the second direction Y and the dimension W22 of the second defining portion P2 along the second direction Y, to the dimension W11 of the first defining portion P1 along the second direction Y or the dimension W22 of the second defining portion P2 along the second direction Y is less than 5%.

As illustrated in FIG. 13 to FIG. 15, the dimension h1 of the first defining portion P1 in the direction perpendicular to the base substrate BS is equal to the dimension h2 of the second defining portion P2 in the direction perpendicular to the base substrate BS.

As illustrated in FIG. 15, the dimension h0 of the main defining portion MP in the direction perpendicular to the base substrate BS is greater than the dimension h1 of the first defining portion P1 in the direction perpendicular to the base substrate BS.

For example, the dimension (height) h0 of the main defining portion MP in the direction perpendicular to the base substrate BS is about 1-2 μm.

For example, the dimension h1 of the first defining portion P1 in the direction perpendicular to the base substrate BS is about 0.5-0.9 μm.

For example, the dimension h2 of the second defining portion P2 in the direction perpendicular to the base substrate BS is about 0.5-0.9 μm.

In the case where no first defining portion P1 and no second defining portion P2 are provided between adjacent main defining portions MP, the printing ink is prone to flow unevenly. Compared with the case where no first defining portion P1 and no second defining portion P2 are provided between adjacent main defining portions MP, providing the first defining portion P1 and the second defining portion P2 between adjacent main defining portions MP facilitates the uniform flow of the printing ink within each sub-pixel group, improves the uniformity of the flow of the printing ink, and facilitates the improvement of a film thickness uniformity at the long edge and the short edge of the sub-pixel.

In the case where the widths and heights of the first defining portion P1 and the second defining portion P2 are respectively identical to each other, it is beneficial to improve the uniformity of the flow of the printing ink, and it is beneficial to improve a film thickness uniformity at the long edge and the short edge of the sub-pixel.

In some embodiments of the present disclosure, the dimension (height) h0 of the main defining portion MP in the direction perpendicular to the base substrate BS is about 1.3 μm, the dimension h1 of the first defining portion P1 in the direction perpendicular to the base substrate BS is about 0.6 μm, and the dimension h2 of the second defining portion P2 in the direction perpendicular to the base substrate BS is about 0.6 μm.

As illustrated in FIG. 13 to FIG. 15, the main defining portion MP may be made of hydrophobic material, and the first defining portion P1 and the second defining portion P2 may be made of hydrophilic material. The first defining portion P1 and the second defining portion P2 may be made of the same film layer by using the same patterning process.

As illustrated in FIG. 2 and FIG. 13, the extension direction of the sub-pixel group 200 is identical to the extension direction of the groove KO. That is, the sub-pixel group 200 extends along the second direction Y, and the groove KO extends along the second direction Y. The extension direction of the sub-pixel group 200 may refer to the extension direction of the long edge of the sub-pixel group 200.

As illustrated in FIG. 2 and FIG. 13, the extension direction of the sub-pixel 100 intersects with the extension direction of the groove KO; further, for example, the extension direction of the sub-pixel 100 is perpendicular to the extension direction of the groove KO. That is, the sub-pixel 100 extends along the first direction X, and the groove KO extends along the second direction Y. The extension direction of the sub-pixel 100 may refer to the extension direction of the long edge of the sub-pixel 100.

For example, instead of being parallel to the extension direction of the groove KO, the extension direction of the sub-pixel 100 is set to intersect with the extension direction of the groove KO, which is beneficial to improve a film thickness uniformity.

As illustrated in FIG. 2 and FIG. 13, the extension direction of the groove KO is identical to the extension direction of the main defining portion MP. Thus, the extension direction of the groove KO in the above-mentioned description may also be replaced with the extension direction of the main defining portion MP.

As illustrated in FIG. 2 and FIG. 13, the extension direction of the sub-pixel group 200 is identical to the extension direction of the main defining portion MP. That is, the sub-pixel group 200 extends along the second direction Y, and the main defining portion MP extends along the second direction Y. The extension direction of the sub-pixel group 200 may refer to the extension direction of the long edge of the sub-pixel group 200.

As illustrated in FIG. 2 and FIG. 13, the extension direction of the sub-pixel 100 intersects with the extension direction of the main defining portion MP. Further for example, the extension direction of the sub-pixel 100 is perpendicular to the extension direction of the main defining portion MP. That is, the sub-pixel 100 extends along the first direction X, and the main defining portion MP extends along the second direction Y. The extension direction of the sub-pixel 100 may refer to the extension direction of the long edge of the sub-pixel 100.

For example, instead of being parallel to the extension direction of the main defining portion MP, the extension direction of the sub-pixel 100 is set to intersect with the extension direction of the main defining portion MP, which is beneficial to improve a film thickness uniformity.

It can be contemplated that the relationship between the extension direction of the short edge of the sub-pixel 100 and the extension direction of the main defining portion MP or the groove KO may also be adopted for describing the embodiments.

As illustrated in FIG. 2 and FIG. 13, the extension direction of the short edge of the sub-pixel 100 is identical to the extension direction of the main defining portion MP or the groove KO. That is, the short edge of the sub-pixel 100 extends along the second direction Y, and the main defining portion MP extends along the second direction Y. The extension direction of the sub-pixel 100 may refer to the extension direction of the long edge of the sub-pixel 100.

For example, instead of intersecting with the extension direction of the main defining portion MP, the extension direction of the short edge of the sub-pixel 100 is set to be identical to the extension direction of the main defining portion MP or the groove KO, which is beneficial to improve a film thickness uniformity.

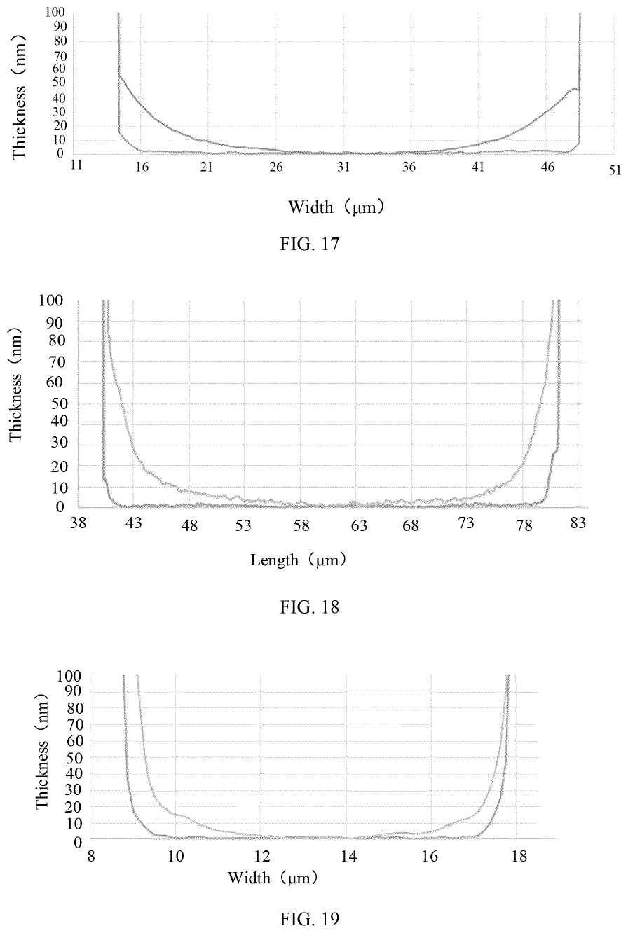

FIG. 16 is a schematic diagram of a film thickness uniformity at the long edge of the sub-pixel of the display substrate illustrated in FIG. 1. FIG. 17 is a schematic diagram of a film thickness uniformity at the short edge of the sub-pixel of the display substrate illustrated in FIG. 1. FIG. 18 is a schematic diagram of a film thickness uniformity at the long edge of the sub-pixel of the display substrate illustrated in FIG. 2. FIG. 19 is a schematic diagram of a film thickness uniformity at the short edge of the sub-pixel of the display substrate illustrated in FIG. 2.

The inner curves in FIG. 16 to FIG. 19 are topography curves of a sub-pixel, and the outer curves are basic curves. The ratio of the length of the horizontal axis corresponding to the overlapping region between the topography curve and the basic curve to the length of the horizontal axis corresponding to the basic curve represents a film thickness uniformity. The area uniformity is a film thickness uniformity of the long edge multiplied by a film thickness uniformity of the short edge.

As illustrated in FIG. 16 and FIG. 17, a film thickness uniformity of the long edge and the short edge of the display substrate illustrated in FIG. 1 are 90% and 50%, respectively, and the area uniformity is 45%.

As illustrated in FIG. 18 and FIG. 19, a film thickness uniformity of the long edge and short edge of the display substrate illustrated in FIG. 2 provided by the embodiments of the present disclosure is 80% and 85%, respectively, the area uniformity may reach 68%, and the pixel uniformity has been significantly improved.

For example, as illustrated in FIG. 2, in the embodiments of the present disclosure, the length W1 of the sub-pixel group 200 may be 5-200 μm, and the width W2 of the sub-pixel group 200 may be 5-100 μm.

Further, for example, the length W1 of the sub-pixel group 200 may be 100-200 μm, and the width W2 of the sub-pixel group 200 may be 10-50 μm.

For example, as illustrated in FIG. 2, in the embodiments of the present disclosure, the length L1 of the sub-pixel 100 may be 2.5-100 μm, and the width L2 of the sub-pixel 100 may be 5-50 μm.

Further, for example, the length L1 of the sub-pixel 100 may be 10-50 μm, and the width L2 of the sub-pixel 100 may be 10-50 μm.

For example, as illustrated in FIG. 2 and FIG. 13, the width of the sub-pixel group 200 is equal to the length of the sub-pixel 100.

For example, as illustrated in FIG. 2 and FIG. 13, the length of the sub-pixel group 200 is at least twice greater than the width of the sub-pixel 100. The length of the sub-pixel group 200 may refer to a distance between two adjacent first defining portions P1.

In some drawings of the embodiments of the present disclosure, the plan view illustrates the first direction X and the second direction Y, and the cross-sectional view illustrates a third direction Z. Both the first direction X and the second direction Y are directions parallel to the main surface of the base substrate BS. The third direction Z is a direction perpendicular to the main surface of the base substrate BS. For example, the first direction X intersects with the second direction Y. The embodiments of the present disclosure take the case where the first direction X is perpendicular to the second direction Y as an example for illustration. For example, the main surface of the base substrate BS is a surface of the base substrate BS on which various elements are manufactured. The upper surface of the base substrate BS in the cross-sectional view is the main surface of the base substrate BS.

For example, in the embodiments of the present disclosure, the base substrate BS, the insulation layer ISL1, the insulation layer ISL2, and the pixel defining layer PDL are all made of insulation materials. For example, the base substrate BS includes a flexible material such as polyimide, etc., or a rigid material such as glass, etc., but is not limited thereto. At least one of the insulation layer ISL1, the insulation layer ISL2, and the pixel defining layer PDL is made of an inorganic insulation material or an organic insulation material. For example, the inorganic insulation material includes silicon oxide, silicon nitride, silicon oxynitride, etc., and the organic insulation material includes resin, but are not limited thereto. For example, the pixel defining layer PDL and the insulation layer ISL1 may be made of an organic material, for example, the organic material includes resin, but is not limited thereto.

For example, in the embodiments of the present disclosure, after the pixel defining layer PDL is formed on the base substrate, at least one film layer in the light-emitting functional layer is manufactured by using the inkjet printing process, and the printing ink is sprayed into the groove KO using the inkjet printing process, and then the at least one film layer in the light-emitting functional layer is formed after vacuum drying, baking, and other operations. For example, the light-emitting layer, the hole transport layer, and the electron transport layer in the light-emitting functional layer may all be manufactured by using the inkjet printing process.

In the embodiments of the present disclosure, the extension direction of a component means that the component extends along its length direction.

At least one embodiment of the present disclosure provides a display device, including any one of the above-mentioned display substrates. The display device may be a large-sized display device, and at least one film layer in the light-emitting functional layer is manufactured by using the inkjet printing process.

What is described above is only specific implementations of the present disclosure, the protection scope of the present disclosure is not limited thereto. Any modifications or substitutions easily occur to those skilled in the art within the technical scope of the present disclosure should be within the protection scope of the present disclosure. Therefore, the protection scope of the present disclosure should be based on the protection scope of the claims.

1. A display substrate, comprising a pixel defining layer, wherein the pixel defining layer comprises a pixel defining structure and a plurality of grooves, the plurality of grooves are arranged along a first direction, the groove extends along a second direction, and the second direction intersects with the first direction;
the pixel defining structure comprises a plurality of first defining portions in the groove and arranged along the second direction, and the first defining portion extends along the first direction; and
two adjacent first defining portions in a same groove are configured to define a sub-pixel group, and the sub-pixel group comprises a plurality of sub-pixels.

2. A display substrate, comprising a pixel defining layer, wherein:
the pixel defining layer comprises a pixel defining structure and a plurality of openings penetrating through the pixel defining structure;
the pixel defining structure comprises a plurality of main defining portions, the plurality of main defining portions are arranged along a first direction, the main defining portion extends along a second direction, and the second direction intersects with the first direction;
the pixel defining structure further comprises a plurality of first defining portions between two adjacent main defining portions and arranged along the second direction, and the first defining portion extends along the first direction;
the pixel defining structure further comprises a second defining portion between two adjacent first defining portions, the second defining portion extends along the first direction; and
two adjacent main defining portions and two adjacent first defining portions between the two adjacent main defining portions are configured to define a sub-pixel group, and the sub-pixel group comprises a plurality of sub-pixels.

3. The display substrate according to claim 1, wherein a short edge of the sub-pixel corresponds to a long edge of the sub-pixel group.

4. The display substrate according to claim 1, wherein the plurality of sub-pixels are arranged sequentially along an extension direction of a long edge of the sub-pixel group.

5. The display substrate according to claim 1, wherein an extension direction of a long edge of the sub-pixel is identical to an extension direction of a short edge of the sub-pixel group, and an extension direction of a short edge of the sub-pixel is identical to an extension direction of a long edge of the sub-pixel group.

6. The display substrate according to claim 1, wherein the pixel defining structure further comprises a second defining portion between two adjacent first defining portions, the second defining portion extends along the first direction, and the second defining portion is configured to separate two adjacent sub-pixels in a same sub-pixel group.

7. The display substrate according to claim 2, wherein a plurality of second defining portions are provided, and the plurality of second defining portions are arranged along the second direction.

8. The display substrate according to claim 2, further comprising a base substrate, wherein the pixel defining layer is on the base substrate, and a dimension of the first defining portion in a direction perpendicular to the base substrate is greater than or equal to a dimension of the second defining portion in the direction perpendicular to the base substrate.

9. The display substrate according to claim 1, further comprising a base substrate, wherein the pixel defining layer is on the base substrate, the pixel defining structure further comprises a plurality of main defining portions, the groove is between two adjacent main defining portions of the plurality of main defining portions, and a dimension of the main defining portion in a direction perpendicular to the base substrate is greater than a dimension of the first defining portion in the direction perpendicular to the base substrate.

10. The display substrate according to claim 2, wherein a dimension of the first defining portion along the second direction is greater than or equal to a dimension of the second defining portion along the second direction.

11. The display substrate according to claim 9, wherein the dimension of the main defining portion in the direction perpendicular to the base substrate is greater than the dimension of the first defining portion in the direction perpendicular to the base substrate.

12. The display substrate according to claim 2, wherein the dimension of the first defining portion along the second direction is greater than the dimension of the second defining portion along the second direction.

13. The display substrate according to claim 2, further comprising a light-emitting element, wherein the light-emitting element comprises a first electrode, a second electrode, and a light-emitting functional layer between the first electrode and the second electrode, and the opening is configured to expose a portion of the first electrode.

14. The display substrate according to claim 2, wherein an extension direction of the main defining portion is identical to an extension direction of a short edge of the sub-pixel.

15. The display substrate according to claim 1, wherein an extension direction of the groove is identical to an extension direction of a short edge of the sub-pixel.

16. The display substrate according to claim 1, further comprising a lens layer, wherein the lens layer comprises a plurality of lens units, an extension direction of the lens unit is identical to an extension direction of a long edge of the sub-pixel, and the lens unit covers at least one sub-pixel.

17. (canceled)

18. The display substrate according to claim 16, wherein different sub-pixel groups correspond to different structures of lens units.

19. The display substrate according to claim 16, wherein an orthographic projection of the lens unit on a base substrate overlaps with an orthographic projection of the first defining portion on the base substrate.

20. The display substrate according to claim 1, wherein each of the sub-pixels comprised in the sub-pixel group is driven by an independent pixel circuit.

21. A display device, comprising the display substrate according to claim 1.
